(19) United States
(12) Patent Application Publication
(10) Pub. No.: US 2022/0293553 A1
(43) Pub. Date: Sep. 15, 2022

(54) SEMICONDUCTOR DEVICE AND METHOD OF MANUFACTURING THE SAME

(71) Applicant: Mitsubishi Electric Corporation, Tokyo (JP)

(72) Inventors: Mana NISHINO, Tokyo (JP); Takumi SHIGEMOTO, Tokyo (JP)

(73) Assignee: Mitsubishi Electric Corporation, Tokyo (JP)

(21) Appl. No.: 17/537,788

(22) Filed: Nov. 30, 2021

(30) Foreign Application Priority Data
Mar. 9, 2021 (JP) 2021-037291

(51) Int. Cl. H01L 23/00; H01L 23/498

(52) U.S. Cl. CPC H01L 24/83; H01L 24/32; H01L 23/49894; H01L 2224/32227; H01L 2224/83007; H01L 2224/83815; H01L 2224/83039; H01L 2224/83065

(57) ABSTRACT

Provided is a semiconductor device capable of accurately positioning a semiconductor element with respect to a metal circuit pattern or positioning an insulating substrate with respect to a base plate without using a dedicated positioning jig, thereby being able to be manufactured inexpensively and a method of manufacturing the semiconductor device. The semiconductor device includes: an insulating substrate; and a semiconductor element, wherein the insulating substrate includes an insulating layer and a metal circuit pattern provided on an upper surface of the insulating layer, the semiconductor element is solder joined to an upper surface of the metal circuit pattern, and an oxide film or a nitride film is provided in a region where the semiconductor element is not solder joined in the upper surface of the metal circuit pattern.

### BACKGROUND OF THE INVENTION

### Field of the Invention

The present disclosure relates to a semiconductor device and a method of manufacturing the semiconductor device.

### Description of the Background Art

In a semiconductor device using a power semiconductor element, for example, an insulating substrate and a base plate or a metal circuit pattern and a power semiconductor element are joined using a soldering material (for example, Japanese Patent No. 4146321).

In joining the insulating substrate and the base plate or in joining the metal circuit pattern and the power semiconductor element, an expensive positioning jig using a graphite, for example, is used to increase an accuracy of positioning of the insulating substrate and the base plate or positioning the metal circuit pattern and the power semiconductor element.

### SUMMARY

The positioning jig for accurately positioning the semiconductor element with respect to the metal circuit pattern or positioning the insulating substrate with respect to the base plate to perform solder joining contributes to cost increase.

An object of the present disclosure is to provide a semiconductor device capable of accurately positioning a semiconductor element with respect to a metal circuit pattern or positioning an insulating substrate with respect to a base plate without using a dedicated positioning jig, thereby being able to be manufactured inexpensively.

A semiconductor device according to a first aspect of the present disclosure includes an insulating substrate and a semiconductor element. The insulating substrate includes an insulating layer and a metal circuit pattern provided on an upper surface of the insulating layer. The semiconductor element is solder joined to an upper surface of the metal circuit pattern. An oxide film or a nitride film is provided in a region where the semiconductor element is not solder joined in the upper surface of the metal circuit pattern. Provided accordingly is a semiconductor device capable of accurately positioning a semiconductor element with respect to a metal circuit pattern without using a dedicated positioning jig, thereby being able to be manufactured inexpensively.

These and other objects, features, aspects and advantages of the present invention will become more apparent from the following detailed description of the present invention when taken in conjunction with the accompanying drawings.

### BRIEF DESCRIPTION OF THE DRAWINGS

FIG. 1 is a cross-sectional view illustrating a semiconductor device according to an embodiment 1.

FIG. 2 is a plan view illustrating the semiconductor device according to the embodiment 1.

FIG. 3 is a cross-sectional view illustrating a semiconductor device according to an embodiment 2.

FIG. 4 is a plan view illustrating the semiconductor device according to the embodiment 2.

FIG. 5 is a cross-sectional view illustrating a semiconductor device according to an embodiment 3.

FIG. 6 is a plan view illustrating the semiconductor device according to the embodiment 3.

FIG. 7 is a cross-sectional view illustrating a semiconductor device according to an embodiment 4.

FIG. 8 is a plan view illustrating the semiconductor device according to the embodiment 4.

FIG. 9 is a plan view illustrating a semiconductor device according to an embodiment 5.

FIG. 10 is a plan view illustrating a semiconductor device according to an embodiment 6.

FIG. 11 is a cross-sectional view along an A-A line in FIG. 10 in the semiconductor device according to the embodiment 6.

FIG. 12 is a cross-sectional view along a B-B line in FIG. 10 in the semiconductor device according to the embodiment 6.

FIG. 13 is a cross-sectional view along the A-A line in FIG. 10 in a modification example of the semiconductor device according to the embodiment 6.

FIG. 14 is a cross-sectional view along the B-B line in FIG. 10 in the modification example of the semiconductor device according to the embodiment 6.

FIG. 15 is a cross-sectional view along the A-A line in FIG. 10 in the modification example of the semiconductor device according to the embodiment 6.

FIG. 16 is a cross-sectional view along the B-B line in FIG. 10 in the modification example of the semiconductor device according to the embodiment 6.

FIG. 17 is a flow chart illustrating a method of manufacturing a semiconductor device according to an embodiment.

### DESCRIPTION OF THE PREFERRED EMBODIMENTS

### A. Embodiment 1

<A-1. Configuration>

FIG. 1 is a cross-sectional view illustrating a structure of a semiconductor device 101 according to an embodiment 1.

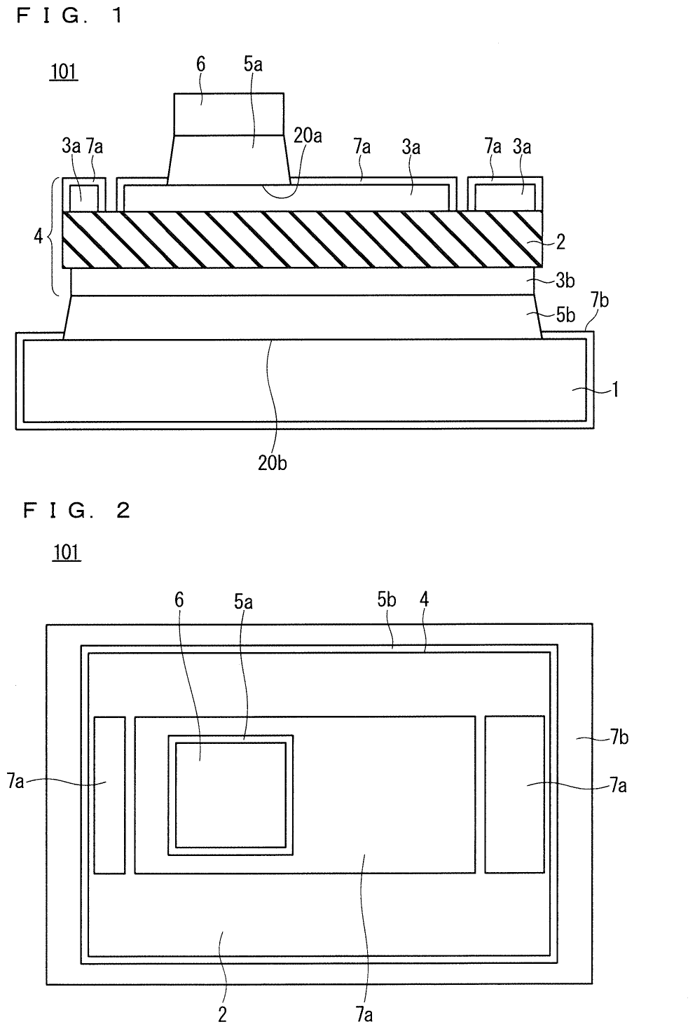

FIG. 2 is a plan view illustrating the structure of the semiconductor device 101 according to the embodiment 1.

The semiconductor device 101 includes a base plate 1, an insulating substrate 4, and a semiconductor element 6.

The insulating substrate 4 includes an insulating layer 2, a metal circuit pattern 3a, and a metal circuit pattern 3b. The metal circuit pattern 3a is provided on one main surface of the insulating layer 2, and the metal circuit pattern 3b is provided on the other main surface of the insulating layer 2.

The metal circuit pattern 3b is solder joined on the base plate 1 via a solder material 5b.

The semiconductor element 6 is solder joined on the metal circuit pattern 3a via the solder material 5a. The semiconductor element 6 is a power semiconductor element, for example.

Each of the solder material 5a and the solder material 5b is a joining material including Sn, for example. The solder material 5a and the solder material 5b may include Pb, for example. Each of the solder material 5a and the solder material 5b may be a brazing material.

In the description hereinafter, a solder joint portion indicates a region where a solder joint is performed in a surface of the metal circuit pattern 3a, the metal circuit pattern 3b, or the base plate 1. The solder joint portion includes a region where a component other than the semiconductor element 6 is solder joined when the component other than the semiconductor element 6 is solder joined on an upper surface of the metal circuit pattern 3a, for example. The solder joint portion includes a region where a component other than the metal circuit pattern 3b is solder joined when the component other than the metal circuit pattern 3b is solder joined on an upper surface of the base plate 1, for example. The region where the semiconductor element 6 is solder joined in the surface of the metal circuit pattern 3a is referred to as a solder joint portion 20a. The region where the metal circuit pattern 3b is solder joined in the surface of the base plate 1 is referred to as a solder joint portion 20b.

An oxide film 7a is provided around the solder joint portion 20a on the upper surface of the metal circuit pattern 3a. The oxide film 7a is provided in a region other than the solder joint portion 20a. The oxide film 7a is provided on an outer side of a region located away from the semiconductor element 6 at a distance of 0.5 mm or less in a plan view, for example, near the solder joint portion 20a. The oxide film 7a is wholly provided on the upper surface and a side surface of the metal circuit pattern 3a other than a region where the other conductor is solder joined or joined by the other method, for example. The oxide film 7a may not be provided on the side surface of the metal circuit pattern 3a.

The oxide film 7a is provided in 95% or more of an area of the region in the upper surface of the metal circuit pattern 3a other than the solder joint portion, for example. That is to say, the oxide film 7a is provided in 95% or more of an area of the region where a solder joint is not performed in the upper surface of the metal circuit pattern 3a, for example. The region where the solder joint is not performed in the upper surface of the metal circuit pattern 3a is a region where no component is solder joined in the upper surface of the metal circuit pattern 3a, and is also a region where the semiconductor element 6 and the other circuit element such as an electrode terminal, for example, is not solder joined. The oxide film 7a is provided in a large range of the upper surface of the metal circuit pattern 3a, thus even if a solder material is scattered at a time of manufacture, the solder material can be easily removed.

The oxide film 7a may be formed in a linear form along a periphery of the semiconductor element 6. A width of the linear oxide film 7a is equal to or larger than 1 mm and equal to or smaller than 2 mm, for example.

An oxide film 7b is provided around the solder joint portion 20b on the upper surface of the base plate 1. The oxide film 7b is provided in a region other than the solder joint portion 20b. The oxide film 7b is provided on an outer side of a region located away from the metal circuit pattern 3b at a distance of 0.5 mm or less in a plan view, for example, near the solder joint portion 20b. The oxide film 7b is wholly provided in the surface of the base plate 1 other than the solder joint portion 20b. The oxide film 7b may not be provided on a side surface or a lower surface of the base plate 1. The oxide film 7b is provided in 95% or more of an area of a region in the upper surface of the base plate 1 other than the solder joint portion, for example. That is to say, the oxide film 7b is provided in 95% or more of an area of a region where a solder joint is not performed in the upper surface of the base plate 1, for example. The region where the solder joint is not performed in the upper surface of the base plate 1 is a region where no component including a component other than the metal circuit pattern 3b is solder joined in the upper surface of the base plate 1. The oxide film 7b is provided in a large range of the upper surface of the base plate 1, thus even if a solder material is scattered at a time of manufacture, the solder material can be easily removed.

The oxide film 7b may be formed in a linear form along a periphery of the metal circuit pattern 3b. A width of the linear oxide film 7b is equal to or larger than 1 mm and equal to or smaller than 2 mm, for example.

A material of the base plate 1 is metal, for example. The metal used as a material of the base plate 1 is copper, copper alloy, aluminum, or aluminum alloy, for example. The material of the base plate 1 may be composite material. The composite material is a composite material of aluminum and silicon carbide or a composite material of magnesium and silicon carbide. The base plate 1 may include a metallic plating appropriate for the solder joint in a surface layer portion. A material of the metallic plating includes nickel, copper, or tin, for example.

A material of the insulating layer 2 may be an inorganic ceramic material or a resin material.

The inorganic ceramic material used as the material of the insulating layer 2 is one of alumina (Al2O3), Aluminum nitride (AlN), silicon nitride (Si3N4), silicon dioxide (SiO2), and boron nitride (BN).

The resin material used as the material of the insulating layer 2 is silicone resin, acrylic resin, polyphenylene sulfide (PPS) resin, or polybutylene terephthalate (PBT) resin, for example.

A material of each of the metal circuit pattern 3a and the metal circuit pattern 3b is metal. The metal used as the material of each of the metal circuit pattern 3a and the metal circuit pattern 3b is copper, copper alloy, aluminum, or aluminum alloy, for example. The material of each of the metal circuit pattern 3a and the metal circuit pattern 3b may be different from each other. Each of the metal circuit pattern 3a and the metal circuit pattern 3b may include a metallic plating appropriate for the solder joint in a surface layer portion. A material of the metallic plating includes nickel, copper, or tin, for example.

The semiconductor device 101 may not include the base plate 1. In such a case, a lower surface of the metal circuit pattern 3b is exposed, the insulating layer 2 is formed on an upper surface of the metal circuit pattern 3b, and the metal circuit pattern 3a is formed on an upper surface of the insulating layer 2.

Each of the solder material 5a and the solder material 5b may be formed using a plate-like solder material, or may be formed using a paste-like solder material.

Each of the solder material 5a and the solder material 5b may or may not contain flux.

The oxide film 7a suppresses wetting and spreading of the solder material 5a, thus a flow of the solder material 5a to an unnecessary portion is suppressed. Thus, when the semiconductor element 6 is solder joined to the metal circuit pattern 3a, the semiconductor element 6 and the solder material 5a can be positioned without using a dedicated positioning jig. In this manner, the semiconductor device 101 is a semiconductor device which can be manufactured inexpensively. Even if the solder material 5a is scattered around the solder joint portion 20a at a time of melting the solder material 5a, the scattered solder material 5a do not wet, thus the scattered solder material 5a can be easily removed after the solder joint.

The oxide film 7b suppresses wetting and spreading of the solder material 5b, thus a flow of the solder material 5b to an unnecessary portion is suppressed. Thus, when the insulating substrate 4 is solder joined to the base plate 1, the insulating substrate 4 and the solder material 5b can be positioned without using a dedicated positioning jig. In this manner, the semiconductor device 101 is a semiconductor device which can be manufactured inexpensively. Even if the solder material 5b is scattered around the solder joint portion 20b at a time of melting the solder material 5b, the scattered solder material 5b do not wet, thus the scattered solder material 5b can be easily removed after the solder joint.

<A-2. Manufacturing Method>

FIG. 17 is a flow chart illustrating a method of manufacturing the semiconductor device 101.

Firstly, the oxide film 7a is formed on the surface of the metal circuit pattern 3a (Step S1).

Next, the oxide film 7b is formed on the surface of the base plate 1 (Step S2).

Next, the base plate 1 and the metal circuit pattern 3b are solder joined (Step S3).

Next, the metal circuit pattern 3a and the semiconductor element 6 are solder joined (Step S4).

An actual flow of the manufacturing method is not limited to the order of Step S1, Step S2, Step S3, and Step S4, however, any flow is applicable as long as Step S1 is performed before Step S4, and Step S2 is performed before Step S3. Step S1 and Step S2 may be simultaneously performed, and Step S3 and Step S4 may be simultaneously performed. The actual flow of the manufacturing method may be an order of Step S2, Step S1, Step S4, and Step S3, an order of Step S1, Step S2, Step S4, and Step S3, an order of Step S2, Step S1, Step S3, and Step S4, an order of Step S1, Step S4, Step S2, and Step S3, or an order of Step S2, Step S3, Step S1, and Step S4, for example.

In Step S1, for example, the insulating substrate 4 is heated in an atmosphere or an oxygen atmosphere to oxidize the whole surface of each of the metal circuit pattern 3a and the metal circuit pattern 3b, thereby forming an oxide film (an oxide film including the oxide film formed on the solder joint portion 20a in Step S1 is referred to as the oxide film 70a hereinafter), and subsequently, the oxide film 70a in the solder joint portion in the surface of each of the metal circuit pattern 3a and the metal circuit pattern 3b is removed by etching. Accordingly, the oxide film 7a is formed on the surface of the metal circuit pattern 3a.

Also applicable in Step S1 is that the insulating substrate 4 is heated in the atmosphere or oxygen atmosphere while masking is performed on the solder joint portion in the surface of each of the metal circuit pattern 3a and the metal circuit pattern 3b, thereby forming the oxide film 7a. Also applicable is that the surface of each of the metal circuit pattern 3a and the metal circuit pattern 3b other than the solder joint portion is selectively oxidized while the solder joint portion in the surface of each of the metal circuit pattern 3a and the metal circuit pattern 3b is exposed to inactive gas or reducing gas.

In Step S2, for example, the whole surface of the base plate 1 is heated and oxidized in the atmosphere or oxygen atmosphere to form an oxide film (an oxide film including the oxide film formed on the solder joint portion 20b in Step S2 is referred to as the oxide film 70b hereinafter), and subsequently, the oxide film 70b in the solder joint portion is removed by etching to form the oxide film 7b.

Also applicable in Step S2 is that the base plate 1 is oxidized while masking is performed on the solder joint portion in the surface of the base plate 1, thereby forming the oxide film 7b. Also applicable is that the base plate 1 is oxidized while the solder joint portion in the surface of the base plate 1 is exposed to inactive gas or reducing gas, thereby forming the oxide film 7b.

A thermal oxidation or an anode oxidation is applicable as a method of forming the oxide film on the surface of the base plate 1 or the metal circuit pattern 3a at the time of forming the oxide film 7a and the oxide film 7b.

Each of the oxide film 7a formed in Step S1 and the oxide film 7b formed in Step S2 preferably has a thickness so that a remaining oxide film has a masking function of controlling a wetting property on the solder material even when the oxide film 7a or the oxide film 7b are partially reduced in the solder joint process in Step S3 or Step S4.

For example, when each of Step S3 and Step S4 includes a plasma treatment process and a reflow furnace input process in the reducing gas, and the material of each of the base plate 1 and the metal circuit pattern 3a is copper, the oxide film is completely removed in a case where the film thickness of the oxide film is equal to or smaller than several nm, however, the oxide film is hardly removed completely in a case where the film thickness of the oxide is equal to or larger than 20 nm. Accordingly, the thickness of each of the oxide film 7a formed in Step S1 and the oxide film 7b formed in Step S2 is preferably equal to or larger than 20 nm. However, even when the oxide film 7a or the oxide film 7b is thinner than 20 nm, the effect of the oxide film 7a or the oxide film 7b suppressing the wetting and spreading of the solder material in the solder joint process in Step S3 or Step S4 can be obtained. The plasma treatment process included in Step S3 and Step S4 is a process for removing a foreign material or an oxidized material adhering to the surface of the solder joint portion, for example.

When the oxide film is thick, cost for forming the oxide film increases, thus the thickness of each of the oxide film 7a formed in Step S1 and the oxide film 7b formed in Step S2 is preferably equal to or smaller than 2000 nm, for example.

The thickness of each of the oxide film 7a formed in Step S1 and the oxide film 7b formed in Step S2 is equal to or larger than 20 nm and equal to or smaller than 2000 nm, for example.

When the oxide film 70a or the oxide film 70b are formed in the region including the solder joint portion 20a or the solder joint portion 20b in Step S1 or Step S2, and subsequently, the oxide film 70a or the oxide film 70b of the solder joint portion 20a or the solder joint portion 20b is etched to form the oxide film 7a or the oxide film 7b, laser irradiation or a plasma treatment may be applied to the etching. The atmosphere during the etching process is not particularly limited, however, etching in inactive gas is preferable to suppress a new generation of an oxide film in the solder joint portion 20a or the solder joint portion 20b. When a laser or plasma is used, a spot size can be controlled, and a position can be controlled by a numeral control (NC) machine. A jig and tool necessary for applying a solder resist is unnecessary compared with a case where the oxide film 7a or the oxide film 7b is not formed but a solder resist is applied to the surface of the base plate 1 or the metal circuit pattern 3a, thus the semiconductor device 101 can be manufactured inexpensively.

The laser used for etching and partially removing the oxide film 70a or the oxide film 70b by laser irradiation may be a fiber laser or a green laser, for example.

The oxide film 70a and the oxide film 70b are irradiated with laser light, thus the oxide film 70a and the oxide film 70b can be peeled from the solder joint portion 20a and the solder joint portion 20b using evaporation of a material and impact pressure in accordance with a principle of laser cleaning. The oxide film is newly generated on the solder joint portion 20a and the solder joint portion 20b in some cases in accordance with this processing, however, when a film thickness of the oxide film which is newly generated is several nanometers to several tens of nanometers, the oxide film which is newly generated can be reduced by performing the solder joint in the process having the plasma treatment process and the reflow furnace input process in the reducing gas, thus the solder joint is normally performed.

The case where the oxide film is formed on the upper surface of each of the metal circuit pattern 3a and the base plate 1 is described in the embodiment 1, however, any film is applicable to the film formed on the upper surface of each of the metal circuit pattern 3a and the base plate 1 as long as it suppresses the wetting and spreading of the solder material, thus a nitride film is also applicable instead of the oxide film, for example. When the nitride film is provided in place of the oxide film 7a and the oxide film 7b, a region where the nitride film is provided may be the same as the region described above where the oxide film 7a and the oxide film 7b are provided, and a thickness of the nitride film may be the same as that of each of the oxide film 7a and the oxide film 7b described above.

<A-3. Modification Example>

Described in the above <A-1. Configuration> is the configuration that the oxide film 7a is provided on the surface of the metal circuit pattern 3a and the oxide film 7b is provided on the surface of the base plate 1, however, only one of the oxide film 7a and the oxide film 7b may be provided thereon.

The semiconductor device 101 may be a semiconductor module in which an electrode terminal is joined on the metal circuit pattern 3a and the metal circuit patterns 3a or the metal circuit pattern 3a and the semiconductor device 101 are joined by a wire to constitute a circuit, and the semiconductor element 6 and the insulating substrate 4 are further sealed by a sealing material in the configuration described in <A-1. Configuration>, for example. When a conductor such as the electrode terminal is joined on the metal circuit pattern 3a, an oxide film on that portion is removed before the joining, for example.

### B. Embodiment 2

<B-1. Configuration>

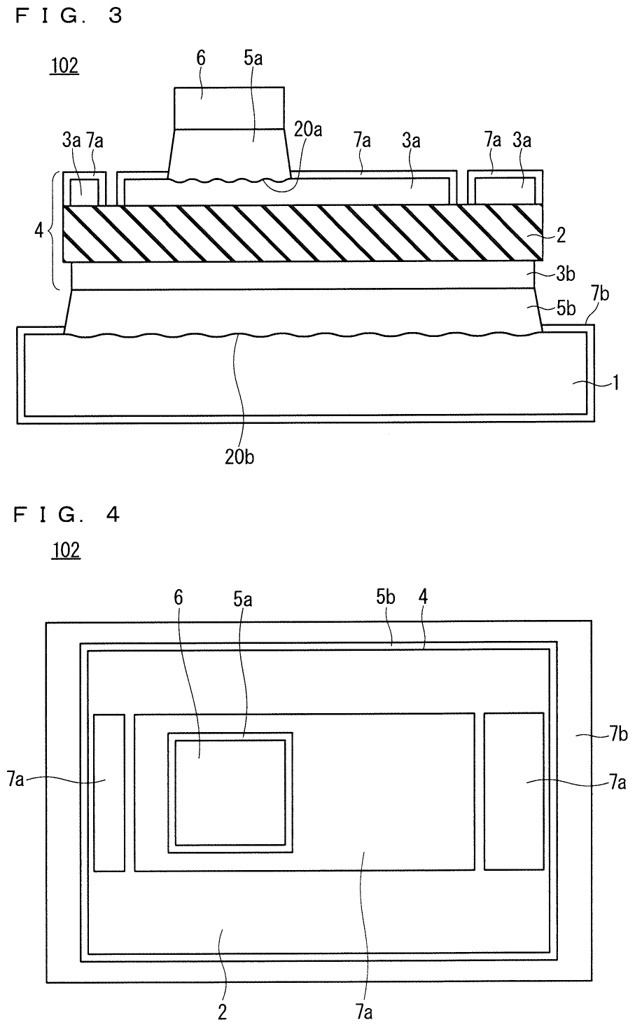

FIG. 3 is a cross-sectional view illustrating a structure of a semiconductor device 102 according to an embodiment 2.

FIG. 4 is a plan view illustrating a structure of the semiconductor device 102 according to the embodiment 2.

The semiconductor device 102 in the embodiment 2 is different from the semiconductor device 101 in the embodiment 1 in that the solder joint portion 20a on the upper surface of the metal circuit pattern 3a and the solder joint portion 20b on the upper surface of the base plate 1 are roughened. The semiconductor device 102 in the embodiment 2 is similar to the semiconductor device 101 in the embodiment 1 in the other point.

The solder joint portion 20a in the upper surface of the metal circuit pattern 3a is rougher than a portion other than the solder joint portion, that is to say, a region where the solder joint is not performed in the upper surface of the metal circuit pattern 3a. The region where the solder joint is not performed in the upper surface of the metal circuit pattern 3a is the region where no component is solder joined in the upper surface of the metal circuit pattern 3a.

The solder joint portion 20b in the upper surface of the base plate 1 is rougher than a portion other than the solder joint portion, that is to say, a region where the solder joint is not performed in the upper surface of the base plate. The region where the solder joint is not performed in the upper surface of the base plate is the region where no component is solder joined in the upper surface of the base plate.

In the present embodiment, the roughness is an arithmetic average roughness Ra regulated in JIS B 0601:2013.

The roughness indicates a roughness of the upper surface of the oxide film 7a or the oxide film 7b in a region where the oxide film 7a or the oxide film 7b is formed on the upper surface of the metal circuit pattern 3a or the base plate 1.

<B-2. Manufacturing Method>

In a method of manufacturing the semiconductor device 102 in the embodiment 2, a process of roughening the upper surface of the metal circuit pattern 3a and the upper surface of the base plate 1 is added to the method of manufacturing the semiconductor device 101 in the embodiment 1. The method of manufacturing the semiconductor device 102 in the embodiment 2 is similar to the method of manufacturing the semiconductor device 101 in the embodiment 1 in the other point.

The solder joint portion 20a is roughened before Step S4. Step S1 may be executed after roughening the solder joint portion 20a to form the oxide film 7a, or it is also applicable that Step S1 is executed to form the oxide film 7a, and then the solder joint portion 20a is roughened. When the oxide film 70a of the solder joint portion 20a is removed after the oxide film 70a is formed in Step S1 to form the oxide film 7a, an order of removing the oxide film 70a of the solder joint portion 20a and roughening the solder joint portion 20a is not particularly limited, however, any of removing and roughening may be performed firstly. Removing of the oxide film 70a of the solder joint portion 20a and roughening of the solder joint portion 20a may be simultaneously performed.

The state where removing of the oxide film 70a of the solder joint portion 20a and roughening of the solder joint portion 20a are simultaneously performed indicates that a time range in which the oxide film 70a of the solder joint portion 20a is removed and a time range in which the solder joint portion 20a is roughened are at least partially overlapped with each other. For example, removing of the oxide film 70a of the solder joint portion 20a and roughening of the solder joint portion 20a are simultaneously performed by a series of laser irradiation in the same process.

When the oxide film 7a is formed after roughening the solder joint portion 20a, in Step S1, the oxide film 70a of the solder joint portion 20a is removed by etching after the oxide film 70a is formed in the region including the roughened solder joint portion 20a, thus the oxide film 7a is formed.

When the solder joint portion 20a is roughened after forming the oxide film 7a, for example, in Step S1, the oxide film 70a of the solder joint portion 20a is removed by etching after the oxide film 70a is formed in the region including the solder joint portion 20a to form the oxide film 7a, and subsequently, the solder joint portion 20a is roughened.

The solder joint portion 20a is roughened by a laser, for example.

The solder joint portion 20b is roughened before Step S3.

Step S2 may be executed after roughening the solder joint portion 20b to form the oxide film 7b, or it is also applicable that Step S2 is executed to form the oxide film 7b, and then the solder joint portion 20b is roughened. When the oxide film 70b of the solder joint portion 20b is removed after the oxide film 70b is formed in Step S2 to form the oxide film 7b, an order of removing the oxide film 70b of the solder joint portion 20b and roughening the solder joint portion 20b is not particularly limited, however, any of removing and roughening may be performed firstly. Removing of the oxide film 70b of the solder joint portion 20b and roughening of the solder joint portion 20b may be simultaneously performed.

The state where removing of the oxide film 70b of the solder joint portion 20b and roughening of the solder joint portion 20b are simultaneously performed indicates that a time range in which the oxide film 70b of the solder joint portion 20b is removed and a time range in which the solder joint portion 20b is roughened are at least partially overlapped with each other. For example, removing of the oxide film 70b of the solder joint portion 20b and roughening of the solder joint portion 20b are simultaneously performed by a series of laser irradiation in the same process.

When the oxide film 7b is formed after roughening the solder joint portion 20b, for example, in Step S2, the oxide film 70b is formed in the region including the roughened solder joint portion 20b, and subsequently, the oxide film 70b of the solder joint portion 20b is removed by etching to form the oxide film 7b.

When the solder joint portion 20b is roughened after forming the oxide film 7b, for example, in Step S2, the oxide film 70b of the solder joint portion 20b is removed by etching after the oxide film 70b is formed in the region including the solder joint portion 20b to form the oxide film 7b, and subsequently, the solder joint portion 20b is roughened.

The solder joint portion 20b is roughened by a laser, for example.

Also in the present embodiment, in the manner similar to the case in the embodiment 1, any order is applicable as an order of performing Step S1, Step S2, Step S3, and Step S4 as long as Step S1 is performed before Step S4, and Step S2 is performed before Step S3.

The order of roughening the solder joint portion 20a and Step S2 is not particularly limited. Any of roughening of the solder joint portion 20a and Step S2 may be performed firstly.

The order of roughening the solder joint portion 20a and Step S3 is not particularly limited. Any of roughening of the solder joint portion 20a and Step S3 may be performed firstly.

The order of roughening the solder joint portion 20b and Step S1 is not particularly limited. Any of roughening of the solder joint portion 20b and Step S1 may be performed firstly.

The order of roughening the solder joint portion 20b and Step S4 is not particularly limited. Any of roughening of the solder joint portion 20b and Step S4 may be performed first.

The order of roughening the solder joint portion 20a and roughening the solder joint portion 20b is not particularly limited. Any of roughening of the solder joint portion 20a and roughening of the solder joint portion 20b may be performed firstly. The solder joint portion 20a and the solder joint portion 20b are roughened in the semiconductor device 102, thus the effect of improving a wetting property of the solder material in the solder joint portion 20a and the solder joint portion 20b and the effect of increasing reliability by increasing a strength of the solder joint by anchor effect can be obtained in addition to the effect in the embodiment 1.

### C. Embodiment 3

FIG. 5 is a cross-sectional view illustrating a structure of a semiconductor device 103 according to an embodiment 3.

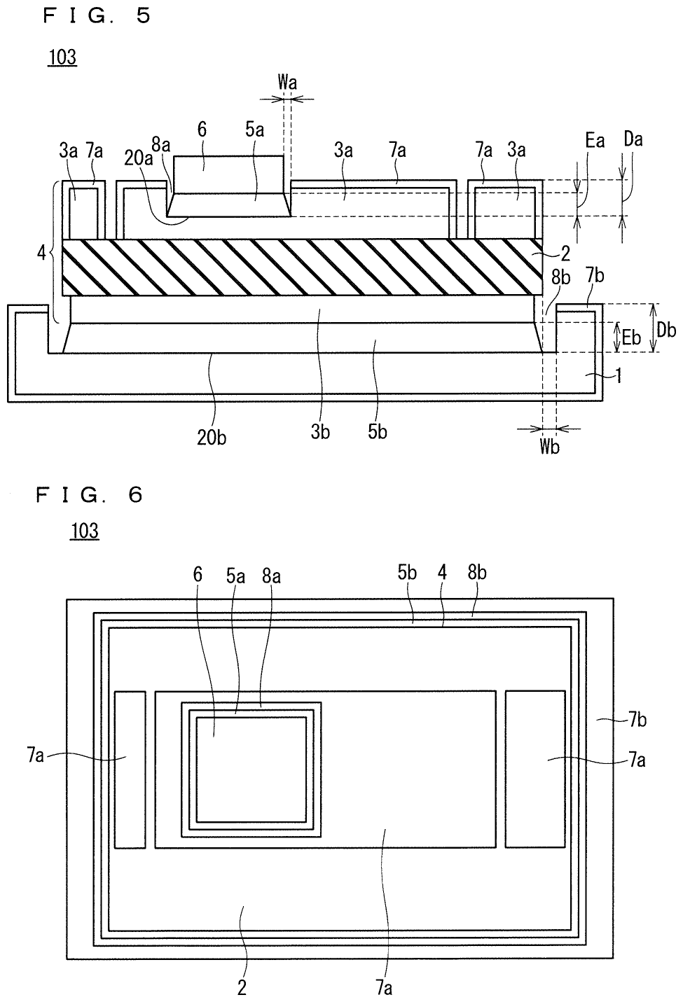

FIG. 6 is a plan view illustrating the structure of the semiconductor device 103 according to the embodiment 3.

The semiconductor device 103 is different from the semiconductor device 101 in the embodiment 1 in that a depression portion 8b is formed in the base plate 1 and a depression portion 8a is formed in the metal circuit pattern 3a. The semiconductor device 103 is similar to the semiconductor device 101 in the embodiment 1 in the other point.

The semiconductor element 6 is solder joined on a bottom surface of the depression portion 8a via the solder material 5a. The insulating substrate 4 is solder joined on the bottom surface of the depression portion 8b via the solder material 5b. Thus, in the semiconductor device 103, obtained is an effect that a positional deviation of the insulating substrate 4 and the semiconductor element 6 can be further suppressed at the time of joining the insulating substrate 4 to the base plate 1 and joining the semiconductor element 6 to the metal circuit pattern 3a in addition to the effect of the semiconductor device 101 in the embodiment 1. Accordingly, the positioning of the semiconductor element 6 and the positioning of the insulating substrate 4 can be performed more easily.

A depth Da of the depression portion 8a is preferably smaller than the thickness of the metal circuit pattern 3a and larger than a thickness Ea of the solder material 5a. The depth Da of the depression portion 8a is equal to or larger than 10 μm, for example.

A depth Db of the depression portion 8b is preferably smaller than the thickness of the base plate 1 and larger than a thickness Eb of the solder material Sb. The depth Db of the depression portion 8b is equal to or larger than 50 μm, for example.

Each of a clearance Wa between a side surface of the depression portion 8a and a side surface of the semiconductor element 6 and a clearance Wb between a side surface of the depression portion 8b and a side surface of the insulating substrate 4 are preferably equal to or larger than 0.2 mm and equal to or smaller than 0.5 mm to sufficiently form a fillet of the solder material 5a and the solder material Sb and ensure a positioning property.

A method of forming the depression portion 8a and the depression portion 8b is not particularly limited, however, a mold press molding or a cutting work is applicable, or laser processing is more preferable. The formation of the depression portion 8a and the depression portion 8b by the laser irradiation is effective for increasing productivity and reducing cost.

The oxide film 7a is formed by forming the oxide film 70a after forming the depression portion 8a, and subsequently etching the oxide film 70a of the solder joint portion. More preferably, after the oxide film 70a is formed, the oxide film 7a is formed by the selective etching of the oxide film 70a of the solder joint portion and the depression portion 8a is formed simultaneously. For example, after the oxide film 70a is formed on the whole surface of the metal circuit pattern 3a, the oxide film 70a of the solder joint portion is selectively etched by the laser irradiation, and the depression portion 8a is formed by the laser simultaneously.

The oxide film 7b is formed by forming the oxide film 70b after forming the depression portion 8b, and subsequently etching the oxide film 70b of the solder joint portion. More preferably, after the oxide film 70b is formed, the oxide film 7b is formed by the selective etching of the oxide film 70b of the solder joint portion and the depression portion 8b is formed simultaneously. For example, the oxide film 70b is formed on the whole surface of the base plate 1, and subsequently, the oxide film 70b of the solder joint portion is selectively etched by the laser irradiation and the depression portion 8b is formed by the laser simultaneously.

The semiconductor device 103 of the present embodiment and the semiconductor device 102 of the embodiment 2 maybe combined with each other. That is to say, the bottom surface of each of the depression portion 8a and the depression portion 8b may be roughened.

### D. Embodiment 4

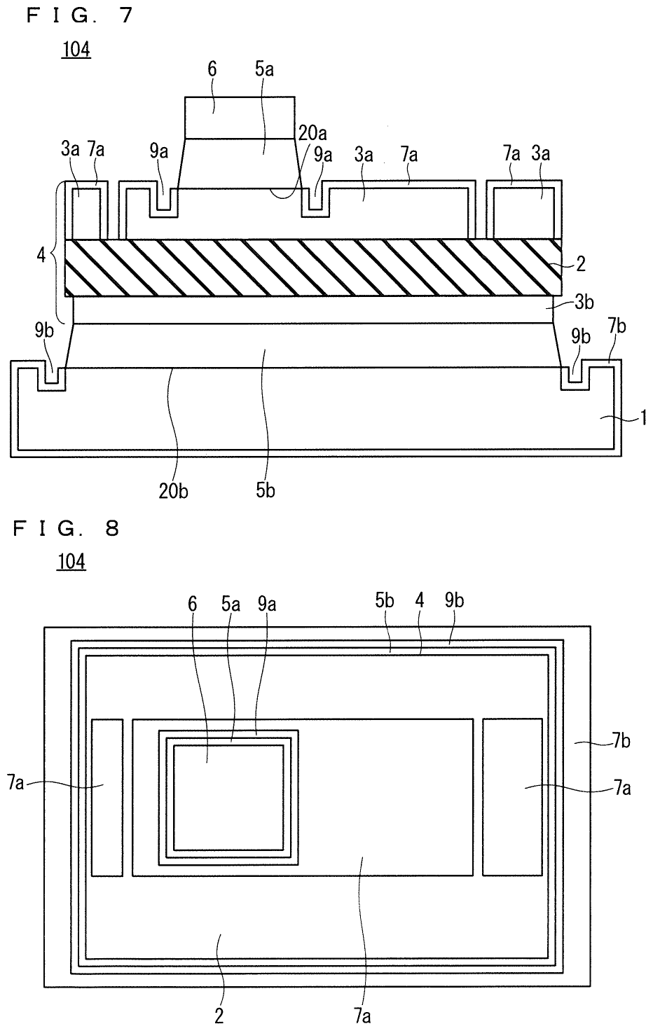

FIG. 7 is a cross-sectional view illustrating a structure of a semiconductor device 104 according to an embodiment 4.

FIG. 8 is a plan view illustrating the structure of the semiconductor device 104 according to the embodiment 4.

The semiconductor device 104 is different from the semiconductor device 101 described in the embodiment 1 in that a groove portion 9a is formed around the solder joint portion 20a of the metal circuit pattern 3a and a groove portion 9b is formed around the solder joint portion 20b of the base plate 1. The semiconductor device 104 is similar to the semiconductor device 101 in the other point.

The groove portion 9a is formed along an outer periphery of the semiconductor element 6 in the upper surface of the metal circuit pattern 3a. The groove portion 9a is formed to continuously surround the semiconductor element 6 in the upper surface of the metal circuit pattern 3a, for example.

A cross-sectional shape of the groove 9a is a rectangular shape as illustrated in FIG. 7, for example.

A region where the oxide film 7a is provided includes a wall surface of the groove portion 9a. A region where the oxide film 7a is provided may partially include the wall surface of the groove portion 9a or may include the whole wall surface of the groove portion 9a. A region where the oxide film 7a is provided includes 95% or more of an area of the wall surface of the groove portion 9a, for example.

The groove portion 9a is disposed not to be overlapped with the semiconductor element 6 in a plan view, for example. The solder joint portion 20a to which the semiconductor element 6 is joined is flat, thus the thickness of the solder material 5a between the semiconductor element 6 and the metal circuit pattern 3a is uniformed, and a quality of joint between the semiconductor element 6 and the metal circuit pattern 3a is stabilized.

The groove portion 9b is formed along an outer periphery of the metal circuit pattern 3b in the upper surface of the base plate 1. The groove portion 9b is formed to continuously surround the metal circuit pattern 3b in the upper surface of the base plate 1.

A cross-sectional shape of the groove 9b is a rectangular shape as illustrated in FIG. 7, for example.

A region where the oxide film 7b is provided includes a wall surface of the groove portion 9b. A region where the oxide film 7b is provided may partially include the wall surface of the groove portion 9b or may include the whole wall surface of the groove portion 9b. A region where the oxide film 7b is provided includes 95% or more of an area of the wall surface of the groove portion 9b, for example.

The groove portion 9b is disposed not to be overlapped with the metal circuit pattern 3b in a plan view, for example. The solder joint portion 20b to which the metal circuit pattern 3b is joined is flat, thus the thickness of the solder material 5b between the metal circuit pattern 3b and the base plate 1 is uniformed, and a quality of joint between the metal circuit pattern 3b and the base plate 1 is stabilized.

The wall surface of the groove portion 9a is the surface of the metal circuit pattern 3a exposed to a portion of the groove portion 9a, and includes a bottom surface and a side surface of the groove portion 9a. The wall surface of the groove portion 9b is the surface of the base plate 1 exposed to a portion of the groove portion 9b, and includes a bottom surface and a side surface of the groove portion 9b.

The groove portion 9a and the groove portion 9b are formed in the semiconductor device 104, thus even if the solder material 5a or the solder material 5b flow, it remains in the groove portion 9a or the groove portion 9b, thus a reliability defect and a characteristic failure due to the flow of the solder material can be suppressed in addition to the effect of the embodiment 1. Accordingly, a short circuit with the other electrical component (not shown) can be prevented. When there are a plurality of semiconductor elements 6, a short circuit with the other semiconductor element 6 can be prevented, and in the similar manner, when there are also a plurality of insulating substrates 4, a short circuit with the other insulating substrates 4 can be prevented.

The groove portion 9a is shallower than the thickness of the metal circuit pattern 3a. A region where the groove portion 9a is provided does not protrude from the metal circuit pattern 3a. When the plurality of semiconductor elements 6 are mounted on the metal circuit pattern 3a, the region where the groove portion 9a is provided does not include the solder joint portion of the other semiconductor element 6 disposed nearby.

The groove portion 9b is shallower than the thickness of the base plate 1. A region where the groove portion 9b is provided does not protrude from the base plate 1. When the plurality of insulating substrates 4 are mounted on the base plate 1, the region where the groove portion 9b is provided does not include the solder joint portion of the other insulating substrate 4 disposed nearby.

A method of forming the groove portion 9a and the groove portion 9b is not particularly limited, however, a mold press molding or a cutting work is applicable, or laser irradiation is more preferable. The formation of the groove portion 9a and the groove portion 9b by the laser irradiation is effective for increasing productivity and reducing cost. The method of forming the groove portion 9a and the method of forming the groove portion 9b may be different from each other, however, the same method is preferable. A procedure is not particularly limited, however, it is also applicable that, for example, the oxide film 70a and the oxide film 70b are formed after forming the groove portion 9a and the groove portion 9b, and subsequently, the oxide film 70a and the oxide film 70b of the solder joint portion are selectively etched to form the oxide film 7a and the oxide film 7b.

### E. Embodiment 5

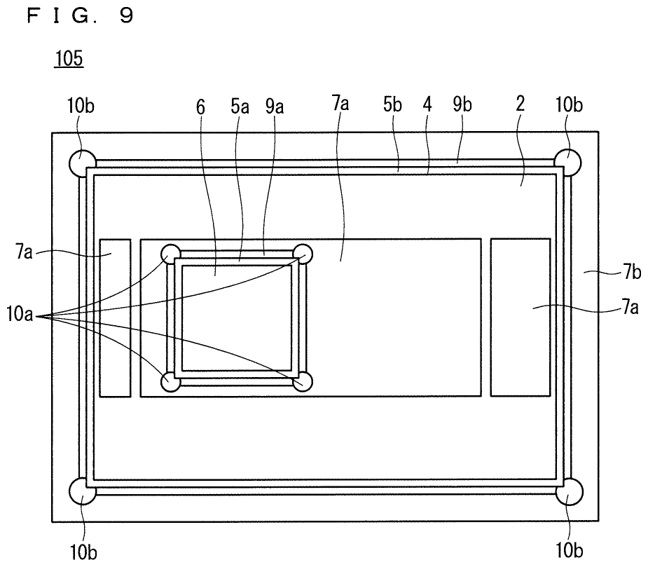

FIG. 9 is a plan view illustrating a structure of a semiconductor device 105 according to an embodiment 5.

The semiconductor device 105 is different from the semiconductor device 104 in the embodiment 4 in that the groove portion 9a includes a wide width portion 10a and the groove portion 9b includes a wide width portion 10b. The semiconductor device 105 is similar to the semiconductor device 104 in the other point.

The wide width portion 10a is a portion of the groove portion 9a having a larger width than the other portion.

The wide width portion 10b is a portion of the groove portion 9b having a larger width than the other portion.

A shape of the semiconductor element 6 in a plan view is a rectangular shape, for example, and a planar shape of the semiconductor element 6, that is to say, the shape in a plan view has a corner. The groove portion 9a includes a wide width portion 10a in a corner portion of the semiconductor element 6. However, the corner portion of the semiconductor element 6 regarding the groove portion 9a is a region near the corner of the semiconductor element 6 in the groove portion 9a, and needs not be overlapped with the corner of the semiconductor element 6 in a plan view. The groove portion 9a includes a wide width portion 10a in each of four corner portions of the semiconductor element 6 having a rectangular shape. A wall surface of the wide width portion 10a includes a portion where the oxide film 7a is not provided. For example, no oxide film 7a is provided in the wall surface of the wide width portion 10a.

A shape of the metal circuit pattern 3b in a plan view is a rectangular shape, for example, and a planar shape of the metal circuit pattern 3b has a corner. The groove portion 9b includes a wide width portion 10b at a corner portion of the metal circuit pattern 3b. However, the corner portion of the metal circuit pattern 3b regarding the groove portion 9b is a region near the corner of the metal circuit pattern 3b in the groove portion 9b, and needs not be overlapped with the corner of the metal circuit pattern 3b. The groove portion 9b includes a wide width portion 10b in each of the four corner portions of the metal circuit pattern 3b having a rectangular shape. A wall surface of the wide width portion 10b includes a portion where the oxide film 7b is not provided. For example, no oxide film 7b is provided in the wall surface of the wide width portion 10b.

The oxide film 7a is not provided on the wall surface of the wide width portion 10a and the oxide film 7b is not provided on the wall surface of the wide width portion 10b, thus even if the solder material 5a or the solder material 5b flows to an unnecessary position, it tends to remain in the wide width portion 10a or the wide width portion 10b. Thus, according to the semiconductor device 105, even if the solder material flows to a surrounding portion, obtained is an effect that a reliability defect and a characteristic failure can be further suppressed in addition to the effect of the embodiment 4.

The oxide film 7a is not provided on the wall surface of the wide width portion 10a and the oxide film 7b is not provided on the wall surface of the wide width portion 10b, thus the solder material firmly adheres to the metal circuit pattern 3a and the base plate 1 in the wide width portion 10a and the wide width portion 10b. Thus, a peeling and a crack of the solder material are suppressed at that portion, and reliability in a temperature cycle can be expected to be improved.

The solder material flowing to the surrounding portion tends to remain in the wide width portion 10a or the wide width portion 10b, and the solder material has a sufficient volume in the wide width portion 10a or the wide width portion 10b, thus even if a crack of the solder material occurs in the wide width portion 10a or the wide width portion 10b, a progression of the crack is suppressed. Thus, a crack of the solder material 5a, which flowed to the wide width portion 10a, reaching and breaking the semiconductor element 6 can be suppressed, and high reliability can be ensured.

A region where the wide width portion 10a is provided does not protrude from the metal circuit pattern 3a. When the plurality of semiconductor elements 6 are mounted on the metal circuit pattern 3a, the region where the wide width portion 10a is provided does not include the solder joint portion of the other semiconductor element 6 disposed nearby.

A region where the wide width portion 10b is provided does not protrude from the base plate 1. When the plurality of insulating substrates 4 are mounted on the base plate 1, the region where the wide width portion 10b is provided does not include the solder joint portion of the other insulating substrate 4 disposed nearby.

A method of forming the wide width portion 10a and the wide width portion 10b is not particularly limited, however, a mold press molding or a cutting work is applicable, or laser irradiation is more preferable. The formation of the wide width portion 10a and the wide width portion 10b by the laser processing is effective for increasing productivity and reducing cost. The method of forming the wide width portion 10a and the method of forming the wide width portion 10b may be different from the method of forming the groove portion 9a and the groove portion 9b, however, the same method is preferable. A procedure of forming the wide width portion 10a and the wide width portion 10b is not particularly limited. For example, it is also applicable that the groove portion 9a and the wide width portion 10a are simultaneously formed, the groove portion 9b and the wide width portion 10b are simultaneously formed, then, the oxide film 70a and the oxide film 70b are formed, and subsequently, the oxide film 70a of the solder joint portion 20a and of the wide width portion 10a, and the oxide film 70b of the solder joint portion 20b and of the wide width portion 10b are selectively etched to form the oxide film 7a and the oxide film 7b.

### F. Embodiment 6

<F-1. Configuration>

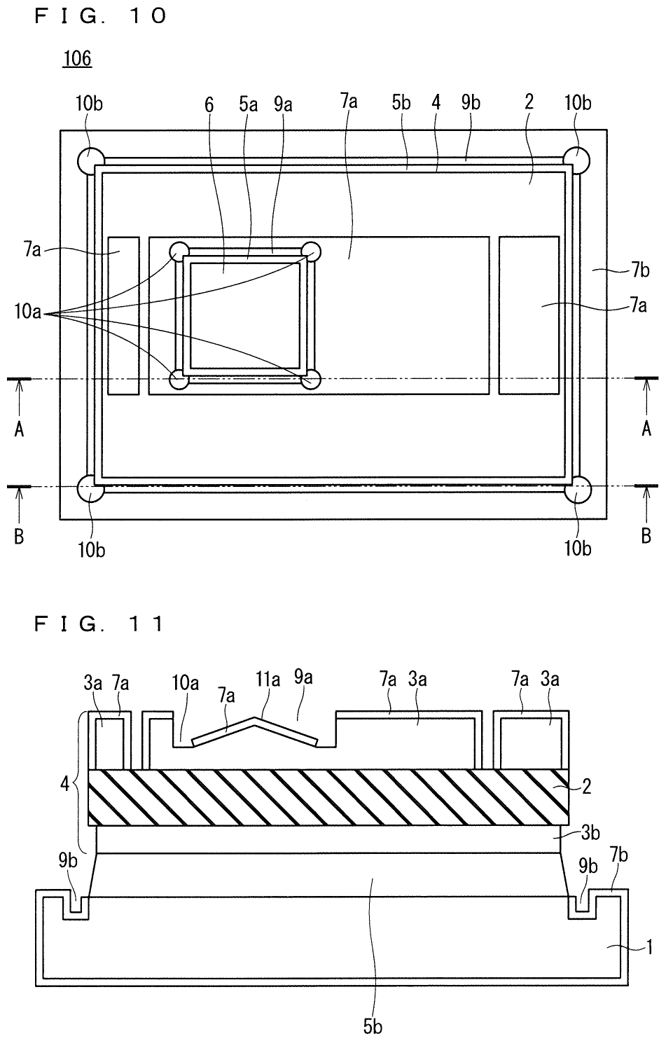

FIG. 10 is a plan view illustrating a structure of a semiconductor device 106 according to an embodiment 6.

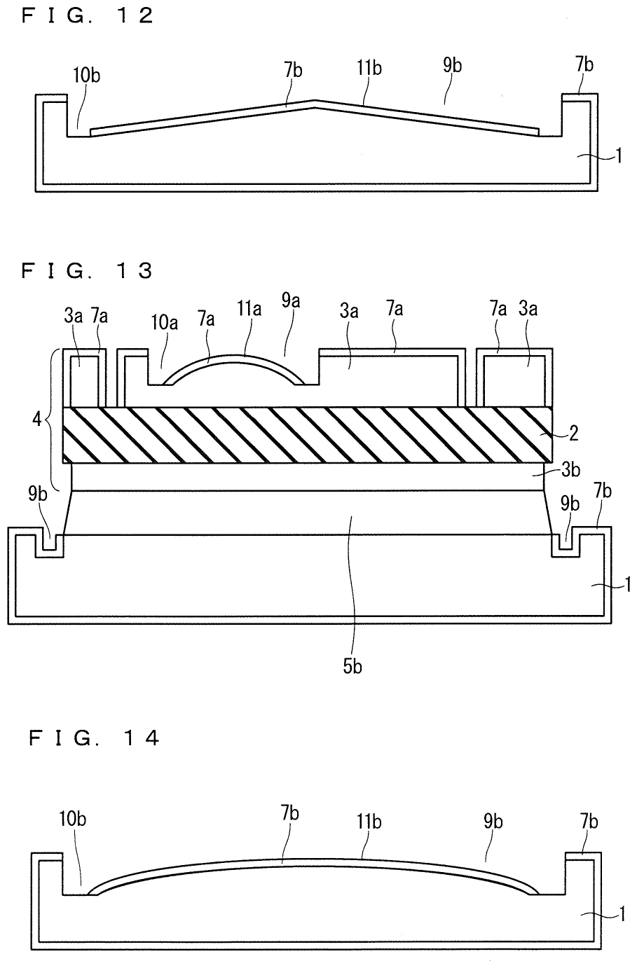

FIG. 11 is a cross-sectional view along an A-A line in FIG. 10. FIG. 12 is a cross-sectional view along a B-B line in FIG. 10.

In the semiconductor device 106, the depth of the groove portion 9a and the depth of the groove portion 9b depend on positions of the groove portion 9a and the groove portion 9b in an extension direction as described hereinafter. The semiconductor device 106 is similar to the semiconductor device 105 described in the embodiment 5 in the other point.

The groove portion 9a is deep in the wide width portion 10a in a corner of the semiconductor element 6 having a rectangular shape in a plan view, and shallower with an increasing distance from the wide width portion 10a in the corner, that is to say, with a decreasing distance from a center portion of the side thereof. In other words, the bottom surface of the groove portion 9a includes an inclined portion 11a.

The groove portion 9a includes the inclined portion 11a, thus even when the solder material 5a flows to a surrounding portion at the time of manufacture, the solder material 5a flowing to the surrounding portion flows along the inclined portion 11a to reach the wide width portion 10a. As a result, even if the solder material 5a flows to an unnecessary position, it further tends to remain in the wide width portion 10a compared with the case in the embodiment 5. Thus, according to the semiconductor device 106, even if the solder material 5a flows to a surrounding portion, obtained is an effect that a reliability defect and a characteristic failure can be further suppressed in addition to the effect of the embodiment 5.

The groove portion 9b is deep in the wide width portion 10b in a corner of the metal circuit pattern 3b having a rectangular shape in a plan view, and shallower with an increasing distance from the wide width portion 10b in the corner, that is to say, with a decreasing distance from a center portion of the side thereof. In other words, the bottom surface of the groove portion 9b includes an inclined portion 11b.

The groove portion 9b includes the inclined portion 11b, thus even when the solder material 5b flows to a surrounding portion at the time of manufacture, the solder material 5b flowing to the surrounding portion flows along the inclined portion 11b to reach the wide width portion 10b. As a result, even if the solder material 5b flows to an unnecessary position, it further tends to remain in the wide width portion 10b compared with the case in the embodiment 5. Thus, according to the semiconductor device 106, even if the solder material 5b flows to a surrounding portion, obtained is an effect that a reliability defect and a characteristic failure can be further suppressed in addition to the effect of the embodiment 5.

The oxide film 7a is not provided on the wall surface of the wide width portion 10a and the oxide film 7b is not provided on the wall surface of the wide width portion 10b, thus the solder material firmly adheres to the metal circuit pattern 3a and the base plate 1 in the wide width portion 10a and the wide width portion 10b. Thus, a peeling and a crack of the solder material are suppressed, and reliability in a temperature cycle can be expected to be improved.

The solder material flowing to the surrounding portion tends to remain in the wide width portion 10a or the wide width portion 10b, and the solder material has a sufficient volume in the wide width portion 10a or the wide width portion 10b, thus even if a crack of the solder material occurs in the wide width portion 10a or the wide width portion 10b, a progression of the crack is suppressed. Thus, a crack of the solder material 5a, which flowed to the wide width portion 10a, reaching and breaking the semiconductor element 6 can be suppressed, and high reliability can be ensured. Thus, the semiconductor device 106 can function as a semiconductor device even in an environment associated with a harder temperature change.

<F-2. Modification Example>

FIG. 13 is a cross-sectional view of a first modification example of the semiconductor device 106 along an A-A line in FIG. 10.

FIG. 14 is a cross-sectional view of the first modification example of the semiconductor device 106 along a B-B line in FIG. 10.

A shape of a top of each of the inclined portion 11 a and the inclined portion 11b, that is to say, a shape of a bottom surface of a shallowest portion of each of the groove portion 9a and the groove portion 9b is not particularly limited, but may be sharpened as illustrated in FIG. 11 or FIG. 12 or an arc-like shape as with the present modification example illustrated in FIG. 13 or FIG. 14.

A way of inclination of the inclined portion 11a is not particularly limited. It is also applicable that the inclined portion 11a has a constant inclination from the top to the wide width portion 10a, an inclination near the top of the inclination portion 11a is larger than that near the wide width portion 10a of the inclination portion 11a, or an inclination near the top of the inclination portion 11a is smaller than that near the wide width portion 10a of the inclination portion 11a.

A way of inclination of the inclined portion 11b is not particularly limited. It is also applicable that the inclined portion 11b has a constant inclination from the top to the wide width portion 10b, an inclination near the top of the inclination portion 11b is larger than that near the wide width portion 10b of the inclination portion 11b, or an inclination near the top of the inclination portion 11b is smaller than that near the wide width portion 10b of the inclination portion 11b.

FIG. 15 is a cross-sectional view of a second modification example of the semiconductor device 106 along an A-A line in FIG. 10.

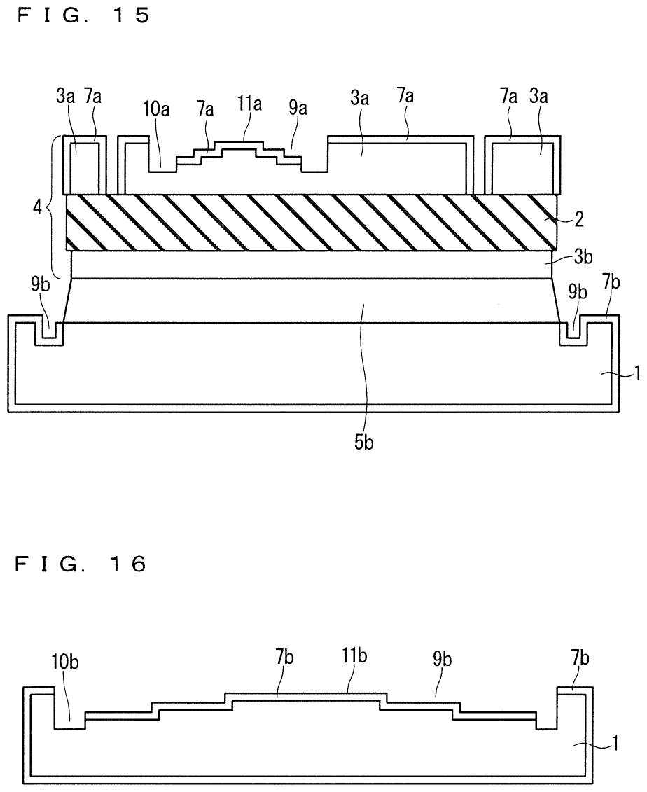

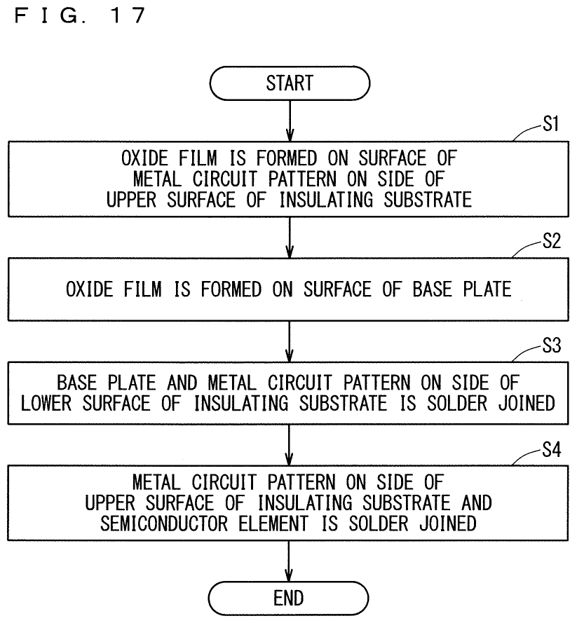

FIG. 16 is a cross-sectional view of the second modification example of the semiconductor device 106 along a B-B line in FIG. 10.

The inclination portion 11a may be made up of a plurality of stages having a height difference, and inclined as a whole as illustrated in FIG. 15. The inclination portion 11b may be made up of a plurality of stages having a height difference, and inclined as a whole as illustrated in FIG. 16. The inclination portion 11a and the inclination portion 11b may not be inclined in each stage, but are preferably inclined in each stage. The inclination portion 11a and the inclination portion 11b are also inclined in each stage, thus the solder material 5a or the solder material 5b flows easily to the wide width portion 10a or the wide width portion 10b.

### G. Embodiment 7

In the embodiments 1 to 6 and the modification examples thereof, the structure of the base plate 1 and the oxide film 7b provided on the surface thereof and the structure of the metal circuit pattern 3a and the oxide film 7a provided on the surface thereof may be independently changed and combined. For example, the structure of the metal circuit pattern 3a and the oxide film 7a provided on the surface thereof in the embodiment 1 and the structure of the base plate 1 and the oxide film 7b provided on the surface thereof in the embodiment 6 and may be combined. Only one of the oxide film 7a and the oxide film 7b may be provided.

Each embodiment can be arbitrarily combined, or each embodiment can be appropriately varied or omitted.

While the invention has been shown and described in detail, the foregoing description is in all aspects illustrative and not restrictive. It is therefore understood that numerous modifications and variations can be devised without departing from the scope of the invention.

What is claimed is:

1. A semiconductor device, comprising:
an insulating substrate; and
a semiconductor element, wherein
the insulating substrate includes an insulating layer and a metal circuit pattern provided on an upper surface of the insulating layer,
the semiconductor element is solder joined to an upper surface of the metal circuit pattern, and
an oxide film or a nitride film is provided in a region where the semiconductor element is not solder joined in the upper surface of the metal circuit pattern.

2. The semiconductor device according to claim 1, wherein
the oxide film or the nitride film is provided in 95% or more of an area of the region where a solder joint is not performed in the upper surface of the metal circuit pattern.

3. The semiconductor device according to claim 1, wherein
the region where the semiconductor element is solder joined in the upper surface of the metal circuit pattern is rougher than the region where the solder joint is not performed in the upper surface of the metal circuit pattern.

4. The semiconductor device according to claim 1, wherein
a depression portion is formed on the upper surface of the metal circuit pattern, and
the semiconductor element is solder joined on a bottom surface of the depression portion.

5. The semiconductor device according to claim 4, wherein
a depth of the depression portion is larger than a thickness of a solder material between the metal circuit pattern and the semiconductor element.

6. The semiconductor device according to claim 1, wherein
a groove portion is formed along an outer periphery of the semiconductor element on the upper surface of the metal circuit pattern, and
a region where the oxide film or the nitride film is provided includes a wall surface of the groove portion.

7. The semiconductor device according to claim 6, wherein
a cross section of the groove portion has a rectangular shape.

8. The semiconductor device according to claim 6, wherein
a region where the oxide film or the nitride film is provided includes 95% or more of an area of the wall surface of the groove portion.

9. The semiconductor device according to claim 6, wherein
a planar shape of the semiconductor element has a corner,
the groove portion includes a wide width portion having a larger width than another portion in a portion of the corner of the semiconductor element, and
a wall surface of the wide width portion includes a portion where the oxide film or the nitride film is not provided.

10. The semiconductor device according to claim 9, wherein
a planar shape of the semiconductor element is a rectangular shape, and
the groove portion includes a wide width portion in each of four corner portions of the semiconductor element having the rectangular shape.

11. The semiconductor device according to claim 9, wherein
the groove portion is shallower with an increasing distance from the wide width portion.

12. The semiconductor device according to claim 6, wherein
the groove portion and the semiconductor element are not overlapped with each other in a plan view.

13. The semiconductor device according to claim 1, wherein
a thickness of the oxide film or the nitride film is equal to or larger than 20 nm and equal to or smaller than 2000 nm.

14. A semiconductor device, comprising:
an insulating substrate;
a semiconductor element; and
a base plate; wherein
the insulating substrate includes an insulating layer, a first metal circuit pattern provided on an upper surface of the insulating layer, and a second metal circuit pattern provided on a lower surface of the insulating layer,
the second metal circuit pattern of the insulating substrate is solder joined to an upper surface of the base plate,
the semiconductor element is solder joined to an upper surface of the first metal circuit pattern, and
an oxide film or a nitride film is provided in a region where the second metal circuit pattern is not solder joined in the upper surface of the base plate.

15. The semiconductor device according to claim 14, wherein
the oxide film or the nitride film is provided in 95% or more of an area of the region where a solder joint is not performed in the upper surface of the base plate.

16. The semiconductor device according to claim 14, wherein
the region where the second metal circuit pattern is solder joined in the upper surface of the base plate is rougher than the region where the solder joint is not performed in the upper surface of the base plate.

17. The semiconductor device according to claim 14, wherein
a depression portion is formed on the upper surface of the base plate, and
the second metal circuit pattern is solder joined on a bottom surface of the depression portion.

18. The semiconductor device according to claim 17, wherein
a depth of the depression portion is larger than a thickness of a solder material between the base plate and the second metal circuit pattern.

19. The semiconductor device according to claim 14, wherein
a groove portion is formed along an outer periphery of the second metal circuit pattern on the upper surface of the base plate, and
a region where the oxide film or the nitride film is provided includes a wall surface of the groove portion.

20. The semiconductor device according to claim 19, wherein
a cross section of the groove portion has a rectangular shape.

21. The semiconductor device according to claim 19, wherein
a region where the oxide film or the nitride film is provided includes 95% or more of an area of the wall surface of the groove portion.

22. The semiconductor device according to claim 19, wherein
a planar shape of the second metal circuit pattern includes a corner,
the groove portion includes a wide width portion having a larger width than another portion in a portion of the corner of the second metal circuit pattern, and
a wall surface of the wide width portion includes a portion where the oxide film or the nitride film is not provided.

23. The semiconductor device according to claim 22, wherein
a planar shape of the second metal circuit pattern is a rectangular shape, and
the groove portion includes a wide width portion in each of four corner portions of the second metal circuit pattern having the rectangular shape.

24. The semiconductor device according to claim 22, wherein
the groove portion is shallower with an increasing distance from the wide width portion.

25. The semiconductor device according to claim 19, wherein
the groove portion and the second metal circuit pattern are not overlapped with each other in a plan view.

26. The semiconductor device according to claim 14, wherein
a thickness of the oxide film or the nitride film is equal to or larger than 20 nm and equal to or smaller than 2000 nm.

27. A method of manufacturing a semiconductor device for manufacturing the semiconductor device according to claim 1, wherein
the oxide film or the nitride film is formed on an upper surface of the metal circuit pattern,
the oxide film or the nitride film of a region where the semiconductor element is to be solder joined in the upper surface of the metal circuit pattern is removed by a laser, and
the semiconductor element is solder joined to the region in which the removal of the oxide film or the nitride film by the laser is performed in the upper surface of the metal circuit pattern.

28. The method of manufacturing the semiconductor device according to claim 27, wherein
the region where the semiconductor element is to be solder joined in the upper surface of the metal circuit pattern is roughened by a laser, and
the semiconductor element is solder joined to the region in which the removal of the oxide film or the nitride film by the laser is performed and the roughening by the laser is performed in the upper surface of the metal circuit pattern.

29. The method of manufacturing the semiconductor device according to claim 28, wherein
after the roughening of the region where the semiconductor element is to be solder joined in the upper surface of the metal circuit pattern by the laser is performed,
the formation of the oxide film or the nitride film on the upper surface of the metal circuit pattern is performed.

30. The method of manufacturing the semiconductor device according to claim 28, wherein
after the formation of the oxide film or the nitride film on the upper surface of the metal circuit pattern is performed,
the roughening of the region where the semiconductor element is to be solder joined in the upper surface of the metal circuit pattern by the laser is performed.

31. The method of manufacturing the semiconductor device according to claim 30, wherein
after the removal of the oxide film or the nitride film of a region where the semiconductor element is to be solder joined in the upper surface of the metal circuit pattern by a laser is performed,
the roughening of the region where the semiconductor element is to be solder joined in the upper surface of the metal circuit pattern by the laser is performed.

32. The method of manufacturing the semiconductor device according to claim 30, wherein
the removal of the oxide film or the nitride film of the region where the semiconductor element is to be solder joined in the upper surface of the metal circuit pattern by the laser and the roughening of the region where the semiconductor element is to be solder joined in the upper surface of the metal circuit pattern by the laser are simultaneously performed.

33. The method of manufacturing the semiconductor device according to claim 27, wherein
in the formation of the oxide film or the nitride film on the upper surface of the metal circuit pattern,
the oxide film having a thickness equal to or larger than 20 nm and equal to or smaller than 2000 nm or the nitride film having a thickness equal to or larger than 20 nm and equal to or smaller than 2000 nm is formed on the upper surface of the metal circuit pattern.

34. A method of manufacturing a semiconductor device for manufacturing the semiconductor device according to claim 14, wherein
the oxide film or the nitride film is formed on an upper surface of the base plate,
the oxide film or the nitride film of a region where the second metal circuit pattern is to be solder joined in the upper surface of the base plate is removed by a laser, and
the second metal circuit pattern is solder joined to the region in which the removal of the oxide film or the nitride film by the laser is performed in the upper surface of the base plate.

35. The method of manufacturing the semiconductor device according to claim 34, wherein
the region where the second metal circuit pattern is to be solder joined in the upper surface of the base plate is roughened by a laser, and
the second metal circuit pattern is solder joined to the region in which the removal of the oxide film or the nitride film by the laser is performed and the roughening by the laser is performed in the upper surface of the base plate.

36. The method of manufacturing the semiconductor device according to claim 35, wherein
after the roughening of the region where the second metal circuit pattern is to be solder joined in the upper surface of the base plate by a laser is performed,
the formation of the oxide film or the nitride film on the upper surface of the base plate is performed.

37. The method of manufacturing the semiconductor device according to claim 35, wherein
after the formation of the oxide film or the nitride film on the upper surface of the base plate is performed, the roughening of the region in which the second metal circuit pattern is to be solder joined in the upper surface of the base plate by the laser is performed.

38. The method of manufacturing the semiconductor device according to claim 37, wherein
after the removal of the oxide film or the nitride film in the region in which the second metal circuit pattern is to be solder joined in the upper surface of the base plate by the laser is performed,
the roughening of the region where the second metal circuit pattern is to be solder joined in the upper surface of the base plate by the laser is performed.

39. The method of manufacturing the semiconductor device according to claim 37, wherein
the removal of the oxide film or the nitride film in the region in which the second metal circuit pattern is to be solder joined in the upper surface of the base plate by the laser and the roughening of the region where the second metal circuit pattern is to be solder joined in the upper surface of the base plate by the laser are simultaneously performed.

40. The method of manufacturing the semiconductor device according to claim 34, wherein
in the formation of the oxide film or the nitride film on the upper surface of the base plate,
the oxide film having a thickness equal to or larger than 20 nm and equal to or smaller than 2000 nm or the nitride film having a thickness equal to or larger than 20 nm and equal to or smaller than 2000 nm is formed on the upper surface of the base plate.
